(19) United States
(12) Patent Application Publication
(10) Pub. No.: US 2026/0136955 A1
(43) Pub. Date: May 14, 2026

(54) STACKED MEMORY SYSTEMS

(71) Applicant: SK hynix Inc., Icheon-si Gyeonggi-do (KR)

(72) Inventor: Joon Yong CHOI, Icheon-si Gyeonggi-do (KR)

(73) Assignee: SK hynix Inc., Icheon-si Gyeonggi-do (KR)

(21) Appl. No.: 19/318,133

(22) Filed: Sep. 3, 2025

Related U.S. Application Data
(60) Provisional application No. 63/720,381, filed on Nov. 14, 2024.
(60) Provisional application No. 63/828,648, filed on Jun. 23, 2025.

(51) Int. Cl. H01L 23/538; H01L 23/367; H01L 25/18; H10B 80/00; H10D 80/30

(52) U.S. Cl. CPC H10W 70/611; H10B 80/00; H10D 80/30; H10W 40/22; H10W 90/00; H10W 90/401; H10W 72/823; H10W 90/288; H10W 90/297

(57) ABSTRACT

A stacked memory system includes a substrate including a first region and a second region, a base die and a core die group stacked in the first region, an integrated chip stacked on the core die group, and a connection die group connected between the integrated chip and the substrate in the second region.

### CROSS-REFERENCE TO RELATED APPLICATIONS

The present application claims benefit under 35 U.S.C § 119(e) to U.S. Provisional Application No. 63/720,381, filed on Nov. 14, 2024, and U.S. Provisional Application No. 63/828,648, filed on Jun. 23, 2025, the entire contents of which applications are incorporated herein by reference.

### BACKGROUND

### 1. Technical Field

The present disclosure relates to stacked memory systems that efficiently dissipate heat.

### 2. Related Art

Stacked memory systems, such as high bandwidth memory (HBM) devices, are used in a wide range of applications due to their high bandwidth and energy efficiency. Unlike conventional memory systems that use parallel data buses, stacked memory systems include a stacked memory device including a base chip and a plurality of memory chips interconnected by through silicon vias (TSVs). The stacked memory device includes a physical interface, such as a physical layer for communicating with a processor. The physical layer is designed for high-speed data transmission and efficient communication.

### SUMMARY

The present disclosure describes a stacked memory system that may include a substrate including a first region and a second region, a base die and a core die group stacked in the first region, an integrated chip stacked on the core die group, and a connection die group connected between the integrated chip and the substrate in the second region.

The present disclosure describes a stacked memory system that may include a substrate including a first region and a second region, a base die and a core die group stacked in a first region, an integrated chip stacked on the base die, and a connection die group connected between the integrated chip and the substrate in the second region.

The present disclosure describes a stacked memory system that may include a substrate including a first region, a second region, and a third region, a base die and a core die group stacked in the first region, an integrated chip stacked on the core die group, a first connection die group connected between the integrated chip and the substrate in the second region, and a second connection die group connected between the integrated chip and the substrate in the third region.

The present disclosure describes a stacked memory system that may include a substrate including a first region, a second region, and a third region, a core die group and a base die stacked in the first region, an integrated chip stacked on the base die, a first connection die group connected between the integrated chip and the substrate in the second region, and a second connection die group connected between the integrated chip and the substrate in the third region.

### BRIEF DESCRIPTION OF THE DRAWINGS

FIG. 1 is a block diagram illustrating a stacked memory system according to an embodiment of the present disclosure.

FIG. 2 illustrates planar shapes of regions included on a substrate in a stacked memory system according to an embodiment of the present disclosure.

FIG. 3 illustrates a stacked memory system according to an embodiment of the present disclosure.

FIG. 4 illustrates planar shapes of regions included on a substrate in a stacked memory system according to an embodiment of the present disclosure.

FIG. 5 is a block diagram illustrating a stacked memory system according to an embodiment of the present disclosure.

FIG. 6 to FIG. 9 illustrate planar shapes of regions included on a substrate in a stacked memory system according to an embodiment of the present disclosure.

### DETAILED DESCRIPTION

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

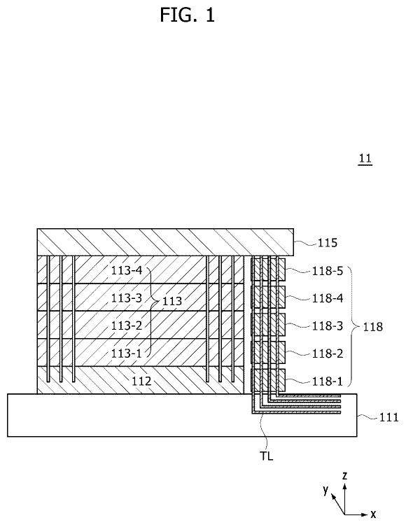

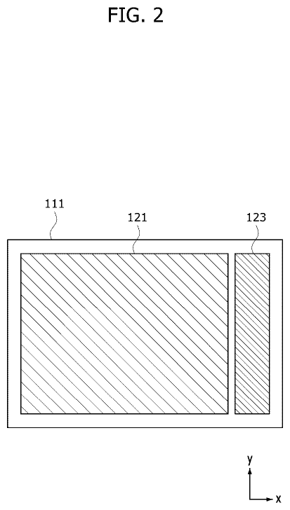

FIG. 1 is a block diagram illustrating a stacked memory system 11 according to an embodiment of the present disclosure, and FIG. 2 illustrates, in a plan view, a first region 121 and a second region 123 included on a substrate 111 in the stacked memory system 11.

As shown in FIG. 1, the stacked memory system 11 includes the substrate 111, a base die 112, a core die group 113, an integrated chip 115, and a connection die group 118. As shown in FIG. 2, the first region 121 and the second region 123 are arranged on an x-y plane of the substrate 111. The first region 121 and the second region 123 are sequentially arranged in a first direction (x direction).

As shown in FIG. 1 and FIG. 2, the base die 112 and the core die group 113 are sequentially stacked in a second direction (z direction) from the substrate 111 in the first region 121. The core die group 113 includes a first cored die 113-1, a second core die 113-2, a third core die 113-3, and a fourth core die 113-4. The base die 112 is stacked in a second direction from the first region 121 included in the substrate 111, the first core die 113-1 is stacked in the second direction from the base die 112, the second core die 113-2 is stacked in the second direction from the first core die 113-1, the third core die 113-3 is stacked in the second direction from the second core die 113-2, and the fourth core die 113-4 is stacked in the second direction from the third core die 113-3.

As shown in FIG. 1 and FIG. 2, the integrated chip 115 is stacked in the second direction (z direction) of the fourth core die 113-4. The integrated chip 115 may be implemented as a system-on-chip (SoC) in which a central processing unit (CPU), a graphic processing unit (GPU), a memory controller, and an input/output interface are integrated into one chip.

As shown in FIG. 1 and FIG. 2, the connection die group 118 is connected to the integrated chip 115 and the second region 123 of the substrate 111. The connection die group 118 includes a first connection die 118-1, a second connection die 118-2, a third connection die 118-3, a fourth connection die 118-4, and a fifth connection die 118-5. The first connection die 118-1 is stacked in the second direction from the substrate 111 in the second region 123, the second connection die 118-2 is stacked in the second direction from the first connection die 118-1, the third connection die 118-3 is stacked in the second direction from the second connection die 118-2, the fourth connection die 118-4 is stacked in the second direction from the third connection die 118-3, and the fifth connection die 118-5 is stacked in the second direction from the fourth connection die 118-4 and connected to the integrated chip 115. The first connection die 118-1, the second connection die 118-2, the third connection die 118-3, the fourth connection die 118-4, and the fifth connection die 118-5 are connected through a plurality of through silicon vias and a plurality of micro bump pads to facilitate signal transmission and heat dissipation. The connection die group 118 includes signal lines TLs connected to an external device (not shown) through the substrate 111 to electrically connect the integrated chip 115 to the external device. The signal lines TLs are implemented by connecting a plurality of metal wirings, a plurality of through vias, and a plurality of micro bump pads, but the present disclosure is not limited thereto.

The stacked memory system 11 may improve signal transmission efficiency between the integrated chip 115 and the substrate 111 by stacking the integrated chip 115 on the base die 112 and the core die group 113 and may efficiently dissipate heat generated from the integrated chip 115 to the substrate 111 through the connection die group 118.

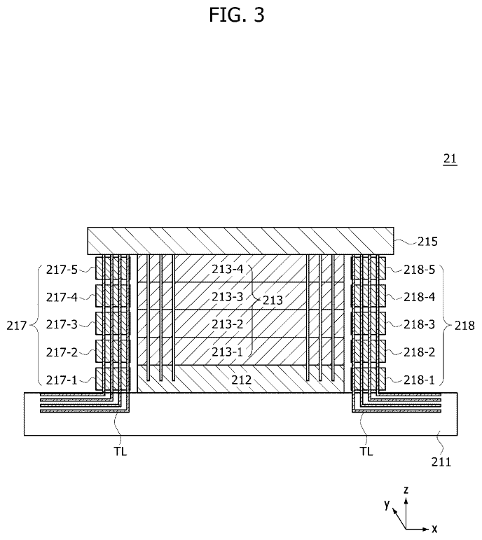

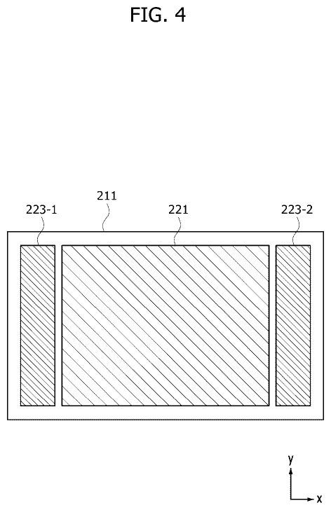

FIG. 3 illustrates a stacked memory system 21 according to an embodiment of the present disclosure, and FIG. 4 illustrates, in a plan view, a first region 221, a second region 223-1, and a third region 223-2 included in a substrate 211 in the stacked memory system 21 according to an embodiment of the present disclosure.

As shown in FIG. 3, the stacked memory system 21 includes the substrate 211, a base die 212, a core die group 213, an integrated chip 215, a first connection die group 217, and a second connection die group 218. As shown in FIG. 4, the first region 221, the second region 223-1, and the third region 223-2 are included on the x-y plane of the substrate 211. The first region 221, the second region 223-1, and the third region 223-2 are sequentially arranged in a first direction (x direction).

As shown in FIG. 3 and FIG. 4, the base die 212 and the cored die group 213 are sequentially stacked in a second direction (z direction) from the substrate 211 in the first region 221. The core die group 213 includes a first core die 213-1, a second core die 213-2, a third core die 213-3, and a fourth core die 213-4. The base die 212 is stacked in a second direction from the first region 221 included in the substrate 211, the first core die 213-1 is stacked in a second direction from the base die 212, the second core die 213-2 is stacked in a second direction from the first core die 213-1, the third core die 213-3 is stacked in a second direction from the second core die 213-3, and the fourth core die 213-4 is stacked in a second direction from the third core die 213-3.

As shown in FIG. 3 and FIG. 4, the integrated chip 215 is stacked in the second direction from the fourth core die 213-4. The integrated chip 215 may be implemented as a system-on-chip (SoC) in which a central processing unit (CPU), a graphic processing unit (GPU), a memory controller, and an input/output interface are integrated into one chip.

As shown in FIG. 3 and FIG. 4, the first connection die group 217 is connected to the integrated chip 215 and the second region 223-1 of the substrate 211. The connection die group 217 includes a first connection die 217-1, a second connection die 217-2, a third connection die 217-3, a fourth connection die 217-4, and a fifth connection die 217-5. The first connection die 217-1 is stacked in the second direction from the substrate 211 in the second region 223-1, the second connection die 217-2 is stacked in the second direction from the first connection die 217-1, the third connection die 217-3 is stacked in the second direction from the second connection die 217-2, the fourth connection die 217-4 is stacked in the second direction from the third connection die 217-3, and the fifth connection die 217-5 is stacked in the second direction from the fourth connection die 217-4 and connected to the integrated chip 215. The first connection die 217-1, the second connection die 217-2, the third connection die 217-3, the fourth connection die 217-4, and the fifth connection die 217-5 are connected through a plurality of through silicon vias and a plurality of micro bump pads to facilitate signal transmission and heat dissipation. The first connection die group 217 includes signal lines TLs connected to an external device (not shown) through the substrate 211 to electrically connect the integrated chip 215 to the external device. The signal lines TLs are implemented by connecting a plurality of metal wirings, a plurality of through vias, and a plurality of micro bump pads, but the present disclosure is not limited thereto.

As shown in FIG. 3 and FIG. 4, the second connection die group 218 is connected to the integrated chip 215 and the third region 223-2 of the substrate 211. The second connection die group 218 includes a sixth connection die 218-1, a seventh connection die 218-2, an eighth connection die 218-3, a ninth connection die 218-4, and a tenth connection die 218-5. The sixth connection die 218-6 is stacked in the second direction from the substrate 211 in the third region 223-2, the seventh connection die 218-2 is stacked in the second direction from the sixth connection die 218-1, the eighth connection die 218-3 is stacked in the second direction from the seventh connection die 218-2, the ninth connection die 218-4 is stacked in the second direction from the eighth connection die 218-3, and the tenth connection die 218-5 is stacked in the second direction from the ninth connection die 218-4 and connected to the integrated chip 215. The sixth connection die 218-1, the seventh connection die 218-2, the eighth connection die 218-3, the ninth connection die 218-4, and the tenth connection die 218-5 are connected through a plurality of through silicon vias and a plurality of micro bump pads to facilitate signal transmission and heat dissipation. The second connection die group 218 includes signal lines TLs connected to an external device (not shown) through the substrate 211 to electrically connect the integrated chip 215 to the external device. The signal lines TLs are implemented by connecting a plurality of metal wirings, a plurality of through vias, and a plurality of micro bump pads, but the present disclosure is not limited thereto.

The stacked memory system 21 may improve signal transmission efficiency between the integrated chip 215 and the substrate 211 by stacking the integrated chip 215 on the base die 212 and the core die group 213 and may efficiently dissipate heat generated from the integrated chip 215 to the substrate 211 through the first connection die group 217 and the second connection die group 218.

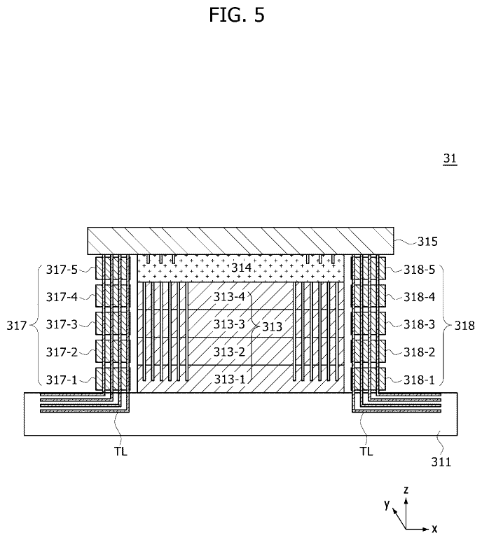

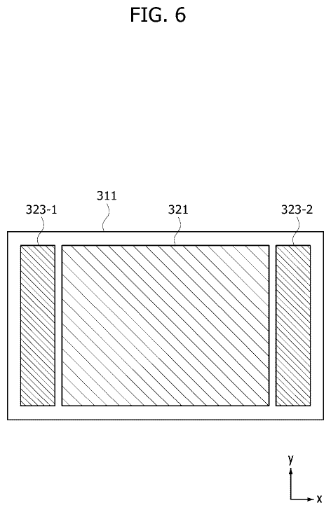

FIG. 5 is a block diagram illustrating a stacked memory system 31 according to an embodiment of the present disclosure, and FIG. 6 illustrates planar shapes of a first region 321, a second region 323-1, and a third region 323-2 included in a substrate 311 in the stacked memory system 31 according to an embodiment of the present disclosure.

As shown in FIG. 5, the stacked memory system 31 includes the substrate 311, a core die group 313, a base die 314, an integrated chip 315, a first connection die group 317, and a second connection die group 318. As shown in FIG. 6, the first region 321, the second region 323-1, and the third region 323-2 are included in the x-y plane of the substrate 311. The first region 321, the second region 323-1, and the third region 323-2 are sequentially stacked in the first direction (x direction).

As shown in FIG. 5 and FIG. 6, the core die group 313 and the base die 314 are sequentially stacked in a second direction (z direction) from the substrate 311 in the first region 321. The core die group 313 includes a first core die 313-1, a second core die 313-2, a third core die 313-3, a fourth core die 313-4. The first core die 313-1 is stacked in the second direction from the substrate 311 in the first region 321, the second core die 313-2 is stacked in the second direction from the first core die 313-1, the third core die 313-3 is stacked in the second direction from the second core die 313-2, the fourth core die 313-4 is stacked in the second direction from the third core die 313-3, and the base die 314 is stacked in the second direction from the fourth core die 313-4.

As shown in FIG. 5 and FIG. 6, the integrated chip 315 is stacked in the second direction from the base die 314. The integrated chip 315 may be implemented as a system-on-chip (SoC) in which a central processing unit (CPU), a graphic processing unit (GPU), a memory controller, and an input/output interface are integrated into one chip.

As shown in FIG. 5 and FIG. 6, the first connection die group 317 is connected to the integrated chip 315 and the second region 323-1 of the substrate 311. The first connection die group 317 includes a first connection die 317-1, a second connection die 317-2, a third connection die 317-3, a fourth connection die 317-4, and a fifth connection die 317-5. The first connection die 317-1 is stacked in the second direction from the substrate 311 in the second region 323-1, the second connection die 317-2 is stacked in the second direction from the first connection die 317-1, the third connection die 317-3 is stacked in the second direction from the second connection die 317-2, the fourth connection die 317-4 is stacked in the second direction from the third connection die 317-3, and the fifth connection die 317-5 is stacked in the second direction from the fourth connection die 317-4 and connected to the integrated chip 315. The first connection die 317-1, the second connection die 317-2, the third connection die 317-3, the fourth connection die 317-4, and the fifth connection die 317-5 are connected through a plurality of through silicon vias and a plurality of micro bump pads to facilitate signal transmission and heat dissipation. The first connection die group 317 includes signal lines TLs connected to an external device (not shown) through the substrate 311 to electrically connect the integrated chip 315 to the external device. The signal lines TLs are implemented by connecting a plurality of metal wirings, a plurality of through vias, and a plurality of micro bump pads, but the present disclosure is not limited thereto.

As shown in FIG. 5 and FIG. 6, the second connection die group 318 is connected to the integrated chip 315 and the third region 323-2 of the substrate 311. The second connection die group 318 includes a sixth connection die 318-1, a seventh connection die 318-2, an eighth connection die 318-3, a ninth connection die 318-4, and a tenth connection die 318-5. The sixth connection die 318-6 is stacked in the second direction from the substrate 311 in the third region 323-2, the seventh connection die 318-2 is stacked in the second direction from the sixth connection die 318-1, the eighth connection die 318-3 is stacked in the second direction from the seventh connection die 318-2, the ninth connection die 318-4 is stacked in the second direction from the eighth connection die 318-3, and the tenth connection die 318-5 is stacked in the second direction from the ninth connection die 318-4 and connected to the integrated chip 315. The sixth connection die 318-1, the seventh connection die 318-2, the eighth connection die 318-3, the ninth connection die 318-4, and the tenth connection die 318-5 are connected through a plurality of through silicon vias and a plurality of micro bump pads to facilitate signal transmission and heat dissipation. The second connection die group 318 includes signal lines TLs connected to an external device (not shown) through the substrate 311 to electrically connect the integrated chip 315 to the external device. The signal lines TLs are implemented by connecting a plurality of metal wirings, a plurality of through vias, and a plurality of micro bump pads, but the present disclosure is not limited thereto.

The stacked memory system 31 may improve signal transmission efficiency between the integrated chip 315 and the substrate 311 and may efficiently dissipate heat generated from the integrated chip 315 to the substrate 311 through the first connection die group 317 and the second connection die group 318 by stacking the integrated chip 215 on the base die 312 and the core die group 313, disposing the separated first connection die group 317 and the second connection die group 318 between the integrated chip 315 and the substrate 311.

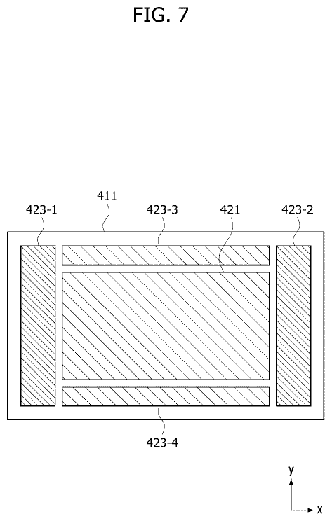

FIG. 7 illustrates planar shapes of a first region 421, a second region 423-1, a third region 423-2, a fourth region 423-3, and a fifth region 423-4 included in a substrate 431 in a stacked memory system according to an embodiment of the present disclosure.

As shown in FIG. 7, the second region 423-1, the first region 421, the fourth region 423-3, the fifth region 423-4, and the third region 423-2 are sequentially disposed in a first direction (x direction). The first region 421, the fourth region 423-3, and the fifth region 423-4 are disposed between the second region 423-1 and the third region 423-2. The fifth region 423-4, the first region 421, and the fourth region 423-3 are sequentially disposed in a third direction (y direction). A core die group, a base die, and an integrated chip may be stacked in the first region 421. In each of the second region 423-1, the third region 423-2, the fourth region 423-3, and the fifth region 423-4, a connection die group capable of transmitting signals between the integrated chip and the substrate 411 and emitting heat from the integrated chip to the substrate 411 may be stacked.

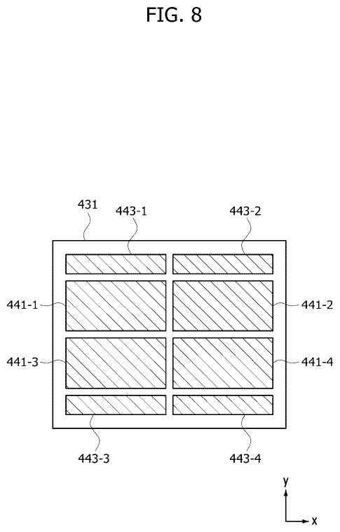

FIG. 8 illustrates planar shapes of a first region 441-1, a second region 441-2, a third region 441-3, a fourth region 441-4, a fifth region 443-1, a sixth region 443-2, a seventh region 443-3, and an eighth region 443-3 included in a substrate 431 in a stacked memory system according to an embodiment of the present disclosure.

As shown in FIG. 8, the first region 441-1 and the second region 441-2 are sequentially disposed in a first direction (x direction), the third region 441-3 and the fourth region 441-4 are sequentially disposed in the first direction, the fifth region 443-1 and the sixth region 443-2 are sequentially disposed in the first direction, and the seventh region 443-3 and the eighth region 443-3 are sequentially disposed in the first direction. The seventh region 443-3, the third region 441-3, the first region 441-1, and the fifth region 443-1 are sequentially disposed in the first direction. The eighth region 443-4, the fourth region 441-4, the second region 441-2, and the sixth region 443-2 are sequentially disposed in the third direction (y direction). In each of the first region 441-1, the second region 441-2, the third region 441-3, and the fourth region 441-4, a core die group, a base die, and an integrated chip may be stacked. In each of the fifth region 443-1, the sixth region 443-2, the seventh region 443-3, and the eighth region 443-4, a connection die group capable of transmitting signals between the integrated chip and the substrate 431 and emitting heat from the integrated chip to the substrate 431 may be stacked.

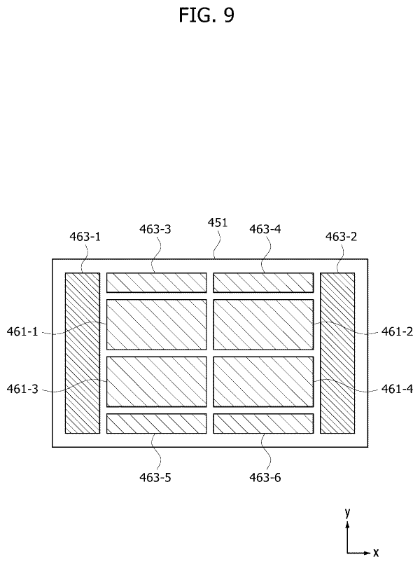

FIG. 9 illustrates planar shapes of a first region 461-1, a second region 461-2, a third region 461-3, a fourth region 461-4, a fifth region 463-1, a sixth region 463-2, a seventh region 463-3, an eighth region 463-3, a ninth region 463-5, and a tenth region 463-6 included in a substrate 451 in a stacked memory system according to an embodiment of the present disclosure.

As shown in FIG. 9, the seventh region 463-3 and the eighth region 463-4 are sequentially disposed in the first direction (x direction) between the fifth region 463-1 and the sixth region 463-2. The first region 461-1 and the second region 461-2 are sequentially disposed in the first direction between the fifth region 463-1 and the sixth region 463-2. The third region 461-3 and the fourth region 461-4 are sequentially disposed in the first direction between the fifth region 463-1 and the sixth region 463-2. The ninth region 463-5 and the tenth region 463-6 are sequentially disposed in the first direction between the fifth region 463-1 and the sixth region 463-2. The ninth region 463-5, the third region 461-3, the first region 461-1, and the seventh region 463-3 are sequentially disposed in the third direction (y direction). The tenth region 463-6, the fourth region 461-4, the second region 461-2, and the eighth region 463-4 are sequentially disposed in the third direction. A core die group, a base die, and an integrated chip may be stacked in each of the first region 461-1, the second region 461-2, the third region 461-3, and the fourth region 461-4. In each of the fifth region 463-1, the sixth region 463-2, the seventh region 463-3, the eighth region 463-4, the ninth region 463-5, and the tenth region 463-6, a connection die group capable of transmitting a signal between the integrated chip and the substrate 451 and discharging heat from the integrated chip to the substrate 451 may be stacked.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A stacked memory system comprising:
a substrate including a first region and a second region;
a base die and a core die group stacked in the first region;
an integrated chip stacked on the core die group; and
a connection die group connected between the integrated chip and the substrate in the second region.

2. The stacked memory system of claim 1, wherein the substrate includes the first region and the second region that are sequentially arranged in a first direction.

3. The stacked memory system of claim 1,
wherein the base die is stacked in a second direction from the substrate in the first region,
wherein the core die group includes a first core die and a second core die,
wherein the first core die is stacked in the second direction from the base die,
wherein the second core die is stacked in the second direction from the first core die, and
wherein the second direction is perpendicular to the first direction.

4. The stacked memory system of claim 3, wherein the integrated chip is stacked in the second direction from the second core die.

5. The stacked memory system of claim 1, wherein the integrated chip is implemented as a system-on-chip (SoC) in which a central processing unit (CPU), a graphic processing unit (GPU), a memory controller, and an input/output interface are integrated into one chip.

6. The stacked memory system of claim 1,
wherein the connection die group includes a first connection die and a second connection die,
wherein the first connection die is stacked in a second direction from the substrate in the second region, and
wherein the second connection die is stacked in the second direction from the first connection die and connected to the integrated chip.

7. A stacked memory system comprising:
a substrate including a first region and a second region;
a base die and a core die group stacked in a first region;
an integrated chip stacked on the base die; and
a connection die group connected between the integrated chip and the substrate in the second region.

8. The stacked memory system of claim 7,
wherein the substrate includes the first region and the second region that are sequentially arranged in a first direction,
wherein the core die group includes a first core die and a second core die,
wherein the first core die is stacked in a second direction from the substrate in the first region,
wherein the second core die is stacked in the second direction from the first core die,
wherein the base die is stacked in the second direction from the second core die included in the substrate, and
wherein the second direction is perpendicular to the first direction.

9. The stacked memory system of claim 8,
wherein the integrated chip is stacked in the second direction of the second core die and implemented as a system-on-chip (SoC) in which a central processing unit (CPU), a graphic processing unit (GPU), a memory controller, and an input/output interface are integrated into one chip.

10. The stacked memory system of claim 7,
wherein the substrate includes the first region and the second region that are sequentially arranged in a first direction,
wherein the connection die group includes a first connection die and a second connection die,
wherein the first connection die is stacked in a second direction from the substrate in the second region,
wherein the second connection die is stacked in the second direction from the first connection die and connected to the integrated chip, and
wherein the second direction is perpendicular to the first direction.

11. A stacked memory system comprising:
a substrate including a first region, a second region, and a third region;
a base die and a core die group stacked in the first region;
an integrated chip stacked on the core die group;
a first connection die group connected between the integrated chip and the substrate in the second region, and
a second connection die group connected between the integrated chip and the substrate in the third region.

12. The stacked memory system of claim 11, wherein the first region, the second region, and the third region are sequentially arranged in a first direction on a plane.

13. The stacked memory system of claim 12,
wherein the base die is stacked in a first direction from the substrate in the first region,
wherein the core die group includes a first core die and a second core die,
wherein the first core die is stacked in the first direction from the base die,
wherein the second core die is stacked in the first direction from the first core die, and
wherein the first direction is perpendicular to the first plane.

14. The stacked memory system of claim 13, wherein the integrated chip is stacked in the first direction of the second core die and implemented as a system-on-chip (SoC) in which a central processing unit (CPU), a graphic processing unit (GPU), a memory controller, and an input/output interface are integrated into one chip.

15. The stacked memory system of claim 12,
wherein the first connection die group includes a first connection die and a second connection die,
wherein the first connection die is stacked in a second direction from the substrate in the second region,
wherein the second connection die is stacked in the second direction from the first connection die and connected to the integrated chip, and
the second direction is perpendicular to the first direction and the plane.

16. The stacked memory system of claim 15,
wherein the second connection die group includes a third connection die and a fourth connection die,
wherein the third connection die is stacked in the second direction from the substrate in the third region, and
wherein the fourth connection die is stacked in the second direction from the third connection die and connected to the integrated chip.

17. A stacked memory system comprising:
a substrate including a first region, a second region, and a third region;
a core die group and a base die stacked in the first region;
an integrated chip stacked on the base die;
a first connection die group connected between the integrated chip and the substrate in the second region, and
a second connection die group connected between the integrated chip and the substrate in the third region.

18. The stacked memory system of claim 17,
wherein the substrate includes the first region, the second region, and the third region that are sequentially arranged in a first direction on a plane,
wherein the core die group includes a first core die and a second core die,
wherein the first core die is stacked in a second direction from the substrate in the first region,
wherein the second core die is stacked in the second direction from the first core die,
wherein the base die is stacked in the second direction from the second core die, and
wherein the second direction is perpendicular to the first direction and the plane.

19. The stacked memory system of claim 18,
wherein the integrated chip is stacked in the first direction of the second core die and implemented as a system-on-chip (SoC) in which a central processing unit (CPU), a graphic processing unit (GPU), a memory controller, and an input/output interface are integrated into one chip.

20. The stacked memory system of claim 17,
wherein the first connection die group includes a first connection die and a second connection die,
wherein the first connection die is stacked in a second direction from the substrate in the second region,
wherein the second connection die is stacked in the second direction from the first connection die and connected to the integrated chip, and
wherein the first direction is perpendicular to the first plane.

21. The stacked memory system of claim 20,
wherein the second connection die group includes a third connection die and a fourth connection die,
wherein the third connection die is stacked in the second direction from the substrate in the third region, and
wherein the fourth connection die is stacked in the second direction from the third connection die and connected to the integrated chip.
